(19) United States
(12) Patent Application Publication
(10) Pub. No.: US 2009/0084600 A1
(43) Pub. Date: Apr. 2, 2009

(54) NANO COATING FOR EMI GASKETS

(75) Inventor: Christopher L. Severance, Derry, NH (US)

Correspondence Address: RISSMAN JOBSE HENDRICKS & OLIVERIO, LLP, 100 Cambridge Street, Suite 2101, BOSTON, MA, 02114, US

(73) Assignee: PARKER HANNIFIN CORPORATION, Cleveland, OH (US)

(21) Appl. No.: 12/241,175

(22) Filed: Sep. 30, 2008

Related U.S. Application Data
(60) Provisional application No. 60/976,937, filed on Oct. 2, 2007.

(51) Int. Cl. H05K 9/00

(52) U.S. Cl. 174/358; 174/351; 361/818

(57) ABSTRACT

EMI shielding gaskets prepared by coating a resilient nonconductive core gasket with a coating or ink containing conductive nanoparticles. The coating layer can be applied at a thickness of 10 microns or less to achieve shielding levels comparable to conventional coatings which are typically an order of magnitude thicker.

### CROSS-REFERENCE TO RELATED APPLICATIONS

This application claims the benefit of U.S. Provisional Application No. 60/976,937 filed on Oct. 2, 2007, the disclosure of which is incorporated herein by reference.

### BACKGROUND OF THE INVENTION

The present invention relates to nanoparticles used as conductive fillers for electromagnetic interference (EMI) shielding coatings and inks. The coatings and inks of this invention are applied to the outer surfaces of gaskets to provide EMI shielding or radio interference (RFI) shielding.

As is known in the art, EMI is radiated or conducted energy that adversely affects the performance of an electronic circuit. EMI and/or RFI may be eliminated or reduced by the use of shielded enclosures and appropriate shielding materials.

The operation of electronic equipment, such as televisions, radios, computers, medical instruments, business machines, communication equipment, and the like, is typically accompanied by the generation of radio frequency and/or electromagnetic radiation within the electronic circuits of an electronic system. The increasing operating frequency in commercial electronic enclosures, such as computers and automotive electronic modules, results in an elevated level of high frequency electromagnetic interference (EMI). Any gap between the metal surfaces mating with doors and access panels of the enclosures for these devices affords an opportunity for the passage of electromagnetic radiation and the creation of electromagnetic interference (EMI). These gaps also interfere with the electric currents running along the surfaces of the cabinets from EMI energy, which is absorbed and is conducted to the ground.

If not properly shielded, such radiation can cause considerable interference with unrelated equipment. Accordingly, it is necessary to effectively shield and ground all sources of radio frequency and electromagnetic radiation within the electronic system. Therefore, it is advisable to use a conducting shield or gasket between such surfaces to block the passage of the electromagnetic interference (EMI radiation).

To attenuate EMI effects, shielding gaskets having the capability of absorbing and/or reflecting EMI energy may be employed both to confine the EMI energy within a source device, and to insulate the device from other source devices. Such shielding is provided as a barrier which is inserted between the source and the other devices, and is typically configured as an electrically conductive and grounded housing which encloses the device. As the circuitry of the device generally must remain accessible for servicing or the like, most housings are provided with removable accesses such as doors, hatches, panels, or covers. Between even the flattest of these accesses and its corresponding mating or faying surface, however, gaps may be present which reduce the efficiency of the shielding by containing openings through which radiant energy may leak or otherwise pass into or out of the device. Moreover, such gaps represent discontinuities in the surface and ground conductivity of the housing or other shielding, and may even generate a secondary source of EMI radiation by functioning as a form of slot antenna. In this regard, bulk or surface currents induced within the housing develop voltage gradients across any interface gaps in the shielding, which gaps thereby function as antennas which radiate EMI noise.

For filling gaps within mating surfaces of housings and other EMI shielding structures, gaskets and seals have been proposed both for maintaining electrical continuity across the structure, and for excluding from the interior of the device such contaminates as moisture and dust. Such seals are bonded or mechanically attached to, or press-fit into, the mating surfaces, and function to close any interface gaps to establish a continuous conductive path across the gap by conforming under an applied pressure to irregularities between the surfaces. Accordingly, seals intended for EMI shielding applications are specified to be of a construction which not only provides electrical surface conductivity even while under compression, but which also has a resiliency allowing the seals to conform to the size of the gap. The seals additionally should be wear resistant, economical to manufacture, and capable of withstanding repeated compression and relaxation cycles.

U.S. Pat. No. 5,008,485, issued to Kitagawa, discloses a conductive EMI shield including an inner sealing member formed of an elastic, nonconductive material such as rubber or the like, and an outer conductive layer coated over the sealing member. Portions of the conductive layer extend beyond the sealing member to directly contact the edges of a housing to which the sealing member is attached. The conductive layer is formed of a conductive compound comprising a resinous material which is filled with carbon black, a metallic powder, or the like to render it electrically conductive.

U.S. Pat. No. 5,028,739, issued to Keyser et al., discloses an EMI shielding gasket including a resilient, elastomeric core enveloped within a fine, open format knit or braided wire mesh. An adhesive strip is disposed lengthwise along a surface of the gasket allowing the gasket to be removably fastened directly to an enclosure.

U.S. Pat. No. 5,105,056, issued to Hoge, Jr., et al., discloses an EMI shielding gasket formed from a conductive sheathing which is wrapped circumferentially around a compressible core. Where the sheathing overlaps itself, a longitudinal seam is defined to which an adhesive is applied for bonding the gasket to a panel of an enclosure or the like.

U.S. Pat. No. 5,202,536, issued to Buonanno, discloses an EMI seal having an elongated resilient core which is covered with a partial conductive sheath. A conductive portion of the sheath, preferably a metalized fabric or the like in a resin binder, is provided to extend partially around the core to define ends which are non-overlapping. A second, nonconductive sheath portion is attached to the core element to extend between the ends of the conductive sheath portion. A contact adhesive may be used to hold the seal in place.

U.S. Pat. No. 6,121,545, issued to Peng et. al., discloses a gasket providing a low closure force, particularly adapted for use in smaller electronic enclosure packages. The disclosed gasket has been designed to form a periodic “interrupted” pattern of alternating local maxima and minima heights.

A typical small enclosure application generally requires a low impedance, low profile connection which is deflectable under relatively low closure force loads. The deflection ensures that the gasket sufficiently conforms to the mating housing or board surfaces to develop an electrically conductive pathway there between. It has been observed that for certain applications, however, the closure or other deflection force required for certain conventional profiles may be higher than can be accommodated by the particular housing or board assembly design.

While the aforementioned and other known gaskets perform reasonably well, these gaskets are relatively costly to assemble in a cabinet. Moreover, the tightly knit wire mesh necessitates that a high closure force is required to seal the door or panel, and the combination of the tightly knit mesh and the required metal clip makes the gasket heavy, which is detrimental in applications where weight is a critical factor such as in the aerospace industry.

As the size of handheld electronic devices, such as cellular phone handsets, has continued to shrink, further improvements in the design of gasket profiles would be well-received by the electronics industry. Specifically, it is desirable to provide a low closure force gasket profile for use in smaller electronics enclosures which are increasingly becoming the industry standard.

The gaskets or seals employed in EMI shielding applications can be made conductive by the incorporation of conductive materials in the raw plastic formulation prior to molding the gasket or seal. Suitable conductive materials for the gaskets and seals include metal or metal-plated particles and fibers. Preferred metals include copper, nickel, silver, aluminum, tin, or an alloy such as Monel, with preferred substrates and fabrics including polyester, polyamide, nylon, and polyimide. Alternatively, other conductive particles and fibers such as carbon or graphite may be used.

The use of electrically conductive inks for static charge dissipation and EMI shielding has also been attempted.

U.S. Pat. No. 5,137,542 describes abrasive articles having a conductive ink printed on the back and/or front surfaces of the articles in a repeating or non-repeating pattern for static dissipation. The conductive ink is described as a liquid dispersion containing a solvent, a resin or polymer, and an electrically conductive pigment. The ink can be cured to a final thickness of less than about 4 microns.

U.S. Pat. No. 6,537,459 is directed to deformable, electrically conductive inks applied to substrates in defined patterns. The electrically conductive ink of the reference is a dispersion of metal (copper, nickel, silver, etc.) or carbon particles and suitable resins in organic solvents. The conductive particles are shaped like plates or flakes having dimensions of between about 1 micron and 0.1 micron. The ink can be applied to a molded part in the form of a pattern which, when dried, can be elongated or deformed while maintaining electrical conductivity. This characteristic is said to provide suitability for EMI shielding applications.

Accordingly, there is a perceived need for an EMI shielding gasket having a resilient core with a structure which is inexpensive and lightweight and allows a low closure force with an enclosing surface. The EMI shielding gasket should also provide superior compression-deflection properties which are highly desirable in complex enclosures.

### SUMMARY OF THE INVENTION

The present invention provides an EMI shielding gasket comprising a resilient, nonconductive core member and a conductive coating or ink. The conductive coating can be a polymer, such as a resin or binding agent, containing conductive nanoparticles. Alternatively, the conductive coating can be a conductive ink comprising nanoparticles dispersed in an aqueous medium.

The nanoparticles of the invention are preferably prepared from EMI absorptive materials, such as carbon or silver. These nanoparticles can be of various shapes and sizes, provided that the maximum dimension of such particles is less than about 100 nm, and preferably less than about 20 nm.

The nanoparticles can be incorporated in a suitable polymer and solvent to form the coating. The polymer can be any of a number of materials suitable for preparing coatings, such as acrylics, polyurethanes, epoxies, silicones, copolymers, and blends thereof, polyvinyl acetate, natural gums and resins, and the like. An ink can be prepared by using an aqueous solution. The amount of nanoparticles present in the coating or ink is typically from about 20% to about 80% by weight on a dry basis.

The coating or ink is applied to the outer surface of the gasket or seal for which it is desired to impart EMI or RFI shielding properties. The thickness of the coating or ink layer depends on the particular application and the degree of shielding desired. In general, the coating or ink layer advantageously has a thickness of less than about 10 microns.

The gasket or seal substrate is a resilient core element having gap-filling capabilities, on which the conductive coating or ink is applied. The resilient core element is typically formed of an electrically conductive elastomeric foam which may be a foamed elastomeric thermoplastic such as polyethylene, polypropylene, polypropylene-EPDM blends, butadiene, styrene-butadiene, nitrile, chlorosulfonate, or a foamed neoprene, urethane, or silicone. Alternatively, an un-foamed silicone, urethane, neoprene, or thermoplastic may be utilized in either solid or tubular form.

Curing or drying of the coating or ink applied to the gasket material will depend on the curing conditions of the polymer and the type of solvent used, i.e. organic or aqueous, for instance. Curing will generally occur at elevated temperatures, i.e. greater than 50° C. or higher, although room temperature curing can be used in some applications.

The gasket or sealing element of this invention provides EMI/RFI shielding and environmental sealing in a number of electronic enclosures, such as doors and access panels, housings for shielding computer cabinets and drives, cathode-ray tubes (CRT) and automotive electronic modules. The gasket or seal can be applied to desired portions or locations of the electronic enclosures.

### BRIEF DESCRIPTION OF THE DRAWINGS

FIG. 1 is a graph comparing the shielding effects of a gasket coated with a conventional coating and a gasket coated with the conductive ink of the present invention.

### DESCRIPTION OF THE PREFERRED EMBODIMENTS

The present invention is directed to EMI shielding gaskets having a nonconductive, resilient core member and a conductive outer layer comprising a polymer or aqueous solution and nanoparticles formed from an electrically conductive or EMI/RFI absorptive material. More particularly, the present invention discloses a resilient gasket or sealing element which provides effective electromagnetic interference (EMI) and/or radio frequency interference (RFI) shielding for adjoining or enclosing surfaces. EMI/RFI shielding effectiveness is provided by coating a non-conductive core element with a polymer or ink containing conductive nanoparticles.

This approach provides an effective shielding solution without compromising the functionality of the gasket or seal in terms of its physical and functional characteristics, i.e. its resiliency. It has been found that the use of conductive nanoparticles in the coating or ink permits the use of extremely thin coatings which have at least equivalent shielding performance characteristics as compared to conventional coatings of substantially greater thicknesses. For example, a coating of about 10 microns prepared according to the present invention has been found to be the equivalent of a conventional coating requiring an order or magnitude greater thickness, both in terms of the electrical conductivity and the shielding performance of the coating. This results in a substantial cost savings and an enhanced improvement in the mechanical performance of the gasket or seal.

Irregularities in surfaces prevent the surfaces from complete mating at all points when the surfaces are brought into contact. The gaps may be minute, but they provide leakage paths for EMI energy, even when very high closure forces are applied. In order to achieve complete mating, a gasket fabricated from a resilient material is installed between the surfaces. When a closure pressure is applied, the gasket conforms itself to the irregularities in both mating surfaces, and accommodates itself to the gradations in local compression throughout the joint, thus sealing it completely. In the same way, if the resilient gasket is coated with a conductive coating or ink, the joint can be sealed against penetration by electromagnetic energy, thereby restoring the conductivity and shielding integrity of the enclosure.

The gasket or seal resilient core element of the invention is typically prepared from a flexible polymeric material having gap filling capabilities around which a conductive ink or coating is provided. Exemplary gasket or sealing materials include elastomeric foamed thermoplastics such as polyethylene, polypropylene, polypropylene-EPDM blends, fluoropolymers, butadiene, styrene-butadiene, nitrile, chlorosulfonate, foamed neoprene, urethane, or silicone, such as an organopolysiloxane. Alternatively, an un-foamed silicone, urethane, neoprene, or thermoplastic may be utilized in either a solid or tubular form.

The performance of an EMI gasket is measured in terms of both electrical and mechanical performance. The mechanical performance generally relates to the closure force during normal operations, with a low closure force being desired. The closure force can be defined as the force required for closing a door or panel while obtaining the necessary deflection of the gasket so as to ensure proper electrical mating of the door to the frame through the gasket. Typically, the closure force required is less than 5 pounds/linear inch. The shielding gaskets should be compressible to a maximum of 75% of their original dimensions without scratching or abrading the mating surfaces.

The electrical performance of an EMI gasket is measured by the surface resistivity in ohm/square at a given compressive load. A low resistivity is desired as this means that the surface conductivity of the gasket is high. EMI shielding performance is measured in decibels over a range of frequencies ranging from 20 MHz to 18 GHz, wherein a constant decibel level over this range is preferred. For most applications, an EMI shielding effectiveness of at least about 10 dB, and usually at least about 20 dB, and preferably at least about 60 dB or higher, over a frequency range of from about 10 MHz to 10 GHz, is considered acceptable.

A conductive coating or ink layer is applied to all or part of the surface of the gasket to achieve the desired EMI shielding effects for a particular application. Suitable application techniques are known in the art and include spray painting, dip coating, roll coating, knife over coating, extrusion, gravure printing, screen printing, flexographic printing, lithographic printing, pad printing, ink jet printing and transfer coating. The coating or ink of the invention is advantageously applied in a selected pattern at a thickness of less than about 10 microns. A suitable printing pattern, by way of example, is a square grid pattern with printed line widths of from about 30 microns to about 100 microns, and line spacings of from about 300 microns to about 900 microns.

The conductive coating or ink comprises a polymer and conductive nanoparticles. The thickness of the coating and the loading of the nanoparticles will define the performance of the gasket. The gasket performance also depends on the thickness and loading of the conductive coating, with a higher loading and thicker coating providing superior shielding performance. Such effectiveness translates to a filler proportion which generally is between about 10-80% by volume or 50-90% by weight, based on the total volume or weight, as the case may be, of the coating, although it is known that comparable EMI shielding effectiveness may be achieved at lower conductivity levels through the use of an EMI absorptive or “lossy” filler.

As used herein, the term “nanoparticle” or “conductive nanoparticle” is intended to define a conductive particle, of a regular or irregular shape, having at least one dimension of less than about 100 nanometers (nm), preferably having all dimensions of less than about 100 nm, and most preferably having at least one dimension or all dimensions of less than about 20 nm. Representative nanoparticle shapes include spheres, spheroids, needles, flakes, platelets, fibers, tubes, etc.

The conductive nanoparticles of the invention can be fabricated from conductive or EMI absorptive materials. Operable conductive materials include silver, carbon, graphite, Monel, copper, steel, nickel, tin, ITO (indium/tin oxide), or any combination thereof. Silver is the least electrically resistant material, while carbon and graphite offer a combination of low electrical resistance and low cost. Operable EMI absorptive materials include ferrite among others.

The nanoparticles are mixed with the polymer binder using known formulation technology. The nanoparticles form a suspension or colloidal mixture in the polymer in the liquid state. When the coating or ink is applied to the gasket substrate and cured to form a solid coating, the particles form a conductive path or circuit on the surface of the gasket, thereby providing the desirable shielding effects.

As used herein, the term “ink” or “conductive ink” refers to a liquid medium having at least the following components: a polymer, a conductive filler and a solvent, preferably an aqueous solvent. The ink can also include other components, such as lubricants, solubilizers, suspension agents, surfactants, and other materials. The terms “polymer”, “resin” and “binder” are frequently used interchangeably herein when referring to inks. However, the key feature of an ink is that it is typically formulated in an aqueous medium and can be readily applied to a surface to impart the desired EMI/RFI shielding properties to the surface. After application, the solvent is removed, i.e. by heating or evaporation at room temperature, for instance, leaving a stable conductive layer on the resilient substrate. Water is typically used as the solvent of choice for inks, although other solvents such as butyl acetate and glycol esters can also be used. A suitable conductive ink for purpose of this invention is manufactured and sold by PChen Associates under the designation PF1200.

Curing of the coating or ink, once applied to the gasket, can be accomplished using conventional techniques, such as room temperature (evaporation), heat curing, ultraviolet (UV) radiation curing, chemical curing, electron beam (EB) or other curing mechanisms, such as anaerobic curing.

The shielding gaskets of the invention may be molded or extruded elements, and may be used, for example, in aircraft applications for electronic bay doors, wing panel access covers, engine pylons, and radomes. Other applications include various electronic enclosures, such as doors and panels, housings for shielding computer cabinets and drives, cathode-ray tubes, automotive electronic modules, and the like. The gaskets can be applied to the desired portions or locations of the electronic enclosures. Gaskets are typically available as either hollow or solid structures, and may be fabricated in a variety of shapes and cross sections.

The following examples illustrate the practical and unique features of the invention herein described. It should be understood that these examples should not be construed in any limiting sense.

### EXAMPLES

A conductive nanoparticle ink formulation was obtained from PChem Associates. The ink, designated as PF1200, is an aqueous formulation containing spherical silver nanoparticles having a nominal size of about 15 mm.

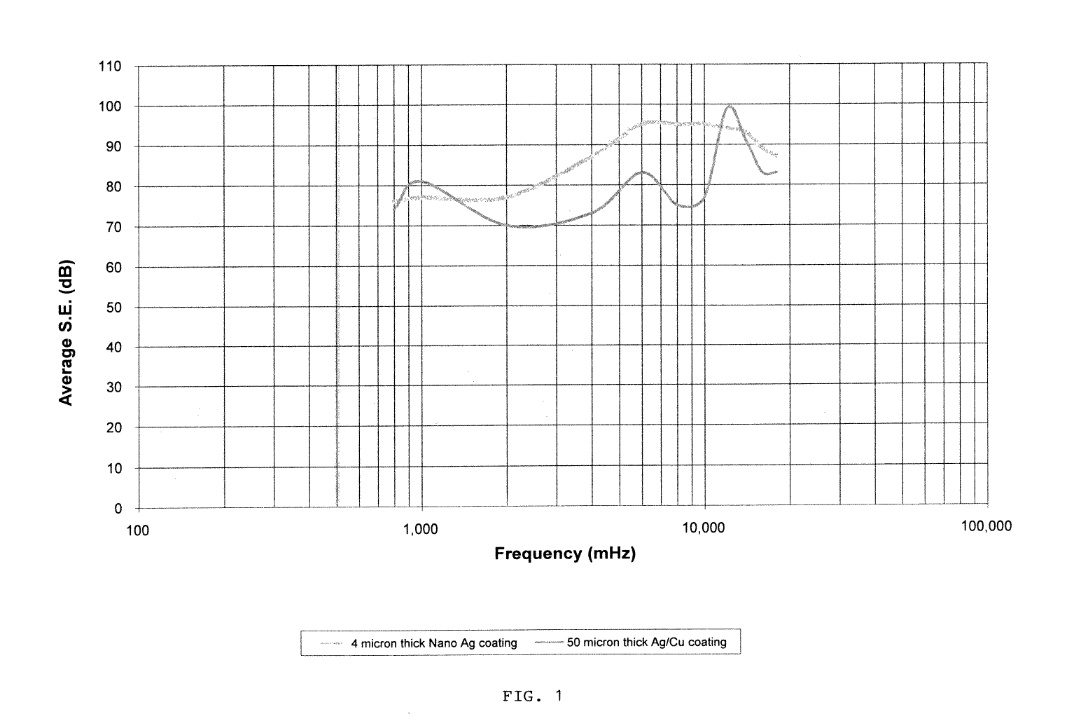

A gasket was coated with the ink using a dip coating process to form a continuous coating over the gasket. A similar gasket was coated with a conventional silver/copper coating. The results are shown in FIG. 1 for comparison wherein the shielding effectiveness is plotted against frequency for each coating.

Various other embodiments are possible and within the spirit and scope of the invention and the appended claims. The aforementioned embodiments are for explanatory purposes only, and are not intended to limit the invention in any manner. The gaskets of the invention can be made in any desired shapes from various kinds of materials available in the field and known to a person skilled in the art. The invention intends to cover all the equivalent embodiments and is limited only by the appended claims. The pertinent disclosures of all patents listed herein are incorporated by reference in their entireties.

1. An EMI shielding gasket comprising:
a resilient nonconductive core gasket having at least an outer surface; and
a shielding layer covering at least a portion of the outer surface of the core gasket member, the shielding layer comprising a filler of electrically conductive and/or EMI absorptive nanoparticles.

2. The EMI shielding gasket of claim 1 wherein the core gasket member is formed from an elastomeric polymeric material or foam.

3. The EMI shielding gasket of claim 1 wherein the shielding layer has a thickness of 10 microns or less.

4. The EMI shielding gasket of claim 1 wherein the shielding layer comprises an admixture of the filler and a binder.

5. The EMI shielding gasket of claim 4 wherein the binder comprises a polymeric material such as a resin or elastomer.

6. The EMI shielding gasket of claim 5 wherein the polymeric material is selected form the group consisting of acrylics, polyurethanes, epoxies, silicones, copolymers, and blends thereof.

7. The EMI shielding gasket of claim 1 wherein the shielding layer is an ink.

8. The EMI shielding layer of claim 7 wherein the ink comprises conductive nanoparticles in an aqueous medium.

9. The nanoparticles of claim 1 which have maximum dimensions of less than about 100 nanometers.

10. The nanoparticles of claim 9 which have maximum dimensions of less than about 20 nanometers.

11. The nanoparticles of claim 1 which are selected from the group consisting of silver, carbon, Monel, copper, steel, nickel, tin, ITO, ferrite, and combinations thereof.
